(19) United States
(12) Patent Application Publication
(10) Pub. No.: US 2024/0318915 A1
(43) Pub. Date: Sep. 26, 2024

(54) MECHATRONIC CURTAIN FOR A PROCESS CHAMBER FOR CARRYING OUT THERMAL PROCESSES IN THE MANUFACTURE OF ELECTRONIC ASSEMBLIES

(71) Applicant: Rehm Thermal Systems GmbH, Blaubeuren-Seissen (DE)

(72) Inventor: Paul WILD, Blaubeuren -Seissen (DE)

(21) Appl. No.: 18/274,694

(22) PCT Filed: Dec. 6, 2021
(86) PCT No.: PCT/EP2021/084383

§ 371 Date: Jul. 27, 2023

(30) Foreign Application Priority Data
Feb. 2, 2021 (DE) 10 2021 102 393.9

(51) Int. Cl. F27D 19/00; F27B 17/00; F27D 7/02; H05K 3/22

(52) U.S. Cl. CPC F27D 19/00; F27B 17/0016; F27D 7/02; F27D 2019/0071; F27D 2019/0084; H05K 3/22; H05K 2203/11

(57) ABSTRACT

The invention relates to a process chamber (10) for carrying out thermal processes in the manufacture of an electronic assembly (30), comprising the following: at least one opening (20) for introducing and/or removing the electronic assembly (30); a device (40) for supplying a gas; a controllable protection device (50) which is arranged on the opening (20) in order to reduce a leakage of gas from the process chamber, wherein the controllable protection device (50) comprises a first movable element (50A) as an integral piece which covers the width between the total width of the opening and the width of the electronic assembly; a device for detecting data relating to the dimensions of the electronic assembly (30); and a controller (60) which can control the protection device (50) on the basis of the data relating to the dimensions of the electronic assembly (30) such that when the electronic assembly (30) passes through the opening (20), a defined spacing is constantly maintained between the electronic assembly and the first movable element (50A).

### FIELD OF THE INVENTION

The present invention relates to devices for carrying out thermal processes in the manufacture of electronic assemblies. The present invention in particular relates to a process chamber according to the preamble of claim 1.

### PRIOR ART

In the manufacture of electronic assemblies, diverse thermal processes take place, such as soldering, drying and function testing at high and low temperatures. To avoid oxidation or icing during the thermal process, the process chamber is, continuously or intermittently, flooded with protective gas, an inert gas such as, for example, nitrogen.

In typical systems for the manufacture of electronic assemblies, the assemblies are automatically transported from one process station to the next one. For example, a printed circuit board is provided, after its production, with a solder-stop lacquer and dried in a process station. Subsequently, the printed circuit board is coated with a solder paste in a further process station and populated with components in a subsequent process station. Subsequently, the populated printed circuit board is forwarded to a reflow solder process station, and then to a station where the electronic assembly is coated with a protective lacquer. Subsequently, function tests can be carried out, for example at low and high temperatures. The individual stations are here no hermetically sealed regions where an protective gas atmosphere is permanently maintained. That means, the process stations are open in order not to hinder the workflow. This also means that the protective gas atmosphere volatilizes, and the concentration of the protective gas atmosphere at the place of the process can only be maintained if shielded gas is constantly supplied.

In the system according to the intermittent and in particular according to the continuously passing-through principle, the work pieces have to be brought into the process chamber and out of it. To this end, the process chamber has to have corresponding openings at and in the chamber. Through these openings, a leakage, and thus a loss of the inert gas, occurs. In order to prevent this, the cross-section of these openings is reduced by a corresponding device for reducing the opening, such as, for example, curtains, bellows, sliding flaps etc.

Here, for example, fin curtains with a plurality of fins hanging down and standing up from the bottom to the top are used, which consist of a tissue laminated with conductive plastic which is temperature-stable up to 260° C., for example. The fins are so stiff that the fins standing from the bottom to the top do not collapse. The fins in the inlet of the process chamber are designed such that they reduce the opening cross-section of a process chamber to the largest cross-sectional area of the assemblies to be supplied. In the outlet of the process chamber, the upper and lower fins are lying one upon the other, i.e. they overlap. However, the fins are flexible enough to bend to the side when an assembly is guided through the opening.

A disadvantage of this method in the inlet and the outlet is that they only reduce the cross-section with a certain spacing to the passing-through workpieces, whereby still a relatively high amount of protective gas can escape. If the spacing is selected to be too long, too much protective gas escapes. If the spacing is selected to be too short, components on the assembly can be shifted, and additionally, too much attrition and wear, and thus too much soiling, occurs when the components touch or bend the fins.

Thus, a compromise between a loss of protective gas and the protection of the assemblies against a shifting of components and against wear is sought for. By the “safety spacing” between the surface of the assembly and the fins, a net opening area remains through which protective gas can escape which corresponds to the difference between the opening area reduced by the fins and the assembly's cross-sectional area. If no assembly is passing through the opening, the opening area through which protective gas can escape corresponds to the net opening area that is larger than the difference area. That means that during the performance of the heating process, when no assembly is passing through the opening, more protective gas escapes.

It is therefore an object of the present invention to provide a device for a process chamber which can flexibly and efficiently adapt the cross-section of the opening to the given conditions (that means, for example, no assembly is passing, a large component of the assembly is passing, a small component of the assembly is passing), so that fewer protective gas can escape.

### Overview of the Invention

The present object is achieved by a process chamber according to claim 1. The process chamber is designed for carrying out thermal processes in the manufacture of an electronic assembly, wherein the process chamber comprises: at least one opening for introducing and/or removing the electronic assembly and a device for supplying a gas, in particular a protective gas. The process chamber is characterized by a controllable protection device which is arranged on the opening in order to reduce a leakage of protective gas from the process chamber, wherein the controllable protection device comprises a first movable element as an integral piece which covers a width between the total width of the opening and the width of the electronic assembly; a device for detecting data relating to the dimensions of the electronic assembly; and a controller which can control the protection device on the basis of the data relating to the dimensions of the electronic assembly such that, when the electronic assembly passes through the opening, a defined spacing becomes constant between the electronic assembly and the first movable element.

That means, when the assembly passes through the opening, the spacing between the assembly surface and the edge of the first movable element facing the assembly is permanently readjusted so that the spacing between an edge of the element and the component of the assembly being the highest one rising from the board remains nearly constantly small at the current passing-through position through the opening. In prior art, the fin curtains are used to reduce the opening cross-section. The fin curtains, however, cannot be controlled. While the flexible fins permit a variability of the assembly's cross-section, they are not able to individually minimize the opening cross-section depending on the assembly and bear the risk of a contact with the components and a damage thereof. A movable element as an integral piece is to be understood in the present context e.g. as a material strip made of one piece, however, these can also be several strip-type parts which are firmly or loosely connected to each other and which are attached to a common mounting and which are moved together (that means not independently).

According to embodiments of the present invention, the electronic assembly consists of a plurality of electronic components which are fastened to an upper side and/or a bottom side of a printed circuit board.

To be able to better consider assemblies that are populated on both sides in the opening control, the controllable protection device can comprise a second movable element as an integral piece which covers a width between the total width of the opening and the width of the electronic assembly, wherein the first movable element and the second movable element are individually controllable and are arranged such that they are disposed above and below the electronic assembly when the electronic assembly passes through the opening.

In order to keep the opening cross-section as small as possible during the passage of printed circuit boards populated on both sides, the controllable protection device (50) can control the second movable element (50A) such that, when the electronic assembly (30) passes the opening (20), a defined spacing between components on the bottom side of the electronic assembly and the second movable element (50A) can be maintained constant.

In a further embodiment, the device for detecting data relating to the dimensions of the electronic assembly furthermore comprises a measuring device which detects the topography or the three-dimensional structure of the electronic assembly, respectively. The measuring device is advantageously arranged at a location of the process chamber where the topography of the electronic assembly can be detected before it passes the opening.

In certain embodiments, the measuring device uses imaging 2D and/or 3D measuring methods, and/or optical measuring methods, and/or mechanical measuring methods, and/or acoustic measuring methods for detecting the topography of the electronic assembly. In order to determine position-dependent height information of the electronic assembly, one or several cameras can be used, for example, to establish a three-dimensional model of the assembly. As an alternative or in support of the evaluation of the camera images, the height information can also be obtained by interferometry with a laser or an array of lasers. As an alternative and in support of the above-mentioned methods, mechanical sampling methods or acoustic methods, such as the generation and evaluation of a sound field, can also be used for obtaining height information.

As an alternative and in support of the above-mentioned methods, the 2D/3D data of the assembly's geometry can be taken from the previous processes, for example the assembly's development and/or the population process.

In one embodiment, the process chamber furthermore includes an actuating device by which the first and/or the second movable element can be simultaneously and independently moved in the vertical direction. Thus, the movable elements can be flexibly employed to maintain the spacings between the assembly and the first or second movable element constant.

As an alternative or supplement to the previous embodiment, the process chamber furthermore includes an actuating device by which the first and/or the second movable element can be simultaneously and independently rotated about a horizontal axis, so that an axis of rotation is located at an end of the movable element opposite the assembly perpendicular to the direction of transport of the assembly. If for the retrofit of the process chamber, no sufficient space for a vertical movement is provided, the spacing can thereby be maintained constant by a swivelling, rotational or flapping movement.

The actuating device can here comprise an electric or pneumatic driving means.

In certain embodiments, the movable elements are made of stainless steel. Stainless steel is an inert, robust material which only slightly tends to corrosion, so that movable elements designed in such a way require only low maintenance and do not influence the processes. Furthermore, stainless steel is conductive and is thus able to conduct away static electricity that can have a negative influence on electronic assemblies. Since stainless steel is furthermore dimensionally very stable, movable elements of stainless steel permit a precise positioning relative to the surface of the electronic assembly and relative to the process chamber.

As an alternative, the movable elements can be made of conductive plastic that is stable up to 240° C., such as e.g. PEEK, if the apparatus costs have to be considered.

### BRIEF DESCRIPTION OF THE FIGURES

The present invention will now be described with reference to the following figures, wherein

FIG. 1 shows a cross-sectional view of a process chamber with a protection device according to the present invention.

### DETAILED DESCRIPTION

The present invention relates to a process chamber for carrying out thermal processes in the manufacture of electronic assemblies. In the manufacture of electronic assemblies, the individual process steps, such as coating, populating, soldering, lacquering, testing etc., are not hermetically separated from each other. The electronic assemblies are transported between the individual processing steps on a transport device between the process stations/process chambers. The process chambers include openings to bring the electronic assemblies into and out of the chamber. That means, the manufacturing process takes place in an open environment which facilitates the workflow. However, the thermal processes take place under an protective gas atmosphere to avoid oxidation. To this end, a local protective gas atmosphere is created by locally supplying protective gas. By the open character of the process sequences, there is a dynamic balance for the protective gas concentration at the site of process, wherein enough protective gas is constantly and locally supplied for the discharge through the openings to be compensated. The smaller the openings are, the less protective gas has to be replenished to maintain a certain concentration at the site of process. The present invention was developed to maintain the open character of the process sequences and to maintain the required openings as small as possible. Thereby, the consumption of protective gas is reduced. Furthermore, a more stable process environment is formed thereby, and the process results are reproducible.

In order to reduce the opening cross-section around the workpiece depending on the assembly, and thus reduce the loss of the inert protective gas, the opening cross-section is actively adapted to the topography of a workpiece. To this end, the topography of the workpiece can first be determined with the aid of 2D and/or 3D imaging, optical, mechanical and/or acoustic measuring methods. As an alternative and/or in support of the above-mentioned methods, the 2D/3D data of the assembly's geometry can be taken from the previous processes, for example the assembly development and/or the population process. On the basis of these data, a movable element controlled pneumatically, electrically or mechanically can minimize a spacing between an edge of the movable element and the assembly's surface, so that the opening cross-section is minimized depending on the topography of the workpiece in the passing-through direction.

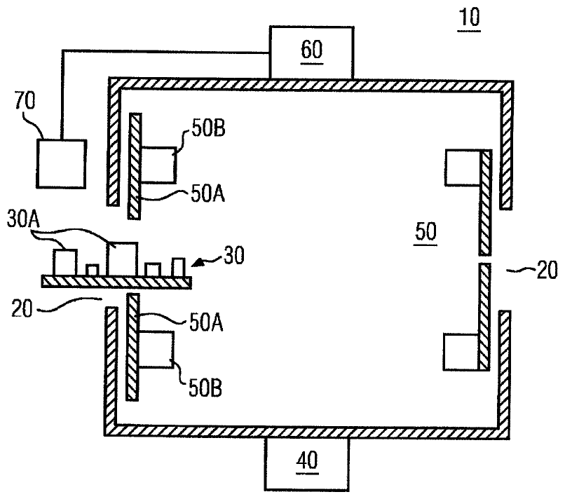

FIG. 1 schematically shows a cross-sectional view of a process chamber according to the present invention. In the cross-section of FIG. 1, reference numeral 10 designates a process chamber, reference numeral 20 an opening, reference numeral 30 an electronic assembly, reference numeral 30A components of the assembly, reference numeral 40 a device for supplying a protective gas, reference numeral 50 a controllable protection device, reference numeral 50A a movable element, reference numeral 50B an actuating device, reference numeral 60 a controller, and reference numeral 70 a measuring device. In FIG. 1, the process chamber 10 is represented with two openings 20 which are provided for introducing or removing the electronic assembly 30, respectively. The movable element 50A is represented as the first and second movable elements which each cover an upper section and lower section of the opening, respectively.

In the arrangement represented in FIG. 1, an assembly 30 is introduced into the process chamber 10. The representation of FIG. 1 shows a condition at a point in time t₁ where the assembly 30 passes the opening 20 of the inlet. At this point in time t₁, the controller 60 has already caused the actuating device 50B of the protection device 50 to retract the first and second movable elements 50A of the protection device 50 to such an extent that the electronic assembly 30 fits through the opening taking into consideration the height of the component 30A currently standing at the location of the protection device. Here, a safety spacing between the movable element 50A and the surface of the component 30A is maintained.

To on the one hand achieve an effective reduction of gas leakage from the process chamber, but on the other hand only involve slight structural efforts, it is advantageous to design the movable elements with a width that is larger than the width of the individual components on the assembly. In this manner, a gap width is maintained constantly small only between the component with the highest extension to the top and the edge of the movable element as an integral piece, i.e. at an adjustable minimum value, but the number of movable elements is also reduced, wherein preferably only one single movable element is provided on one side of the assembly. It is particularly advantageous to configure the movable element with a width corresponding to the width of the gap for the passage of the assemblies. On the other hand, the width of the movable element could correspond to the width of the assembly, that means approximately the width of a printed circuit board on which the components are disposed, or it could be larger, up to the width of the gap. In the latter case, a further arrangement for reducing the leakage of gas is advantageously provided, e.g. one or several stationary, or even laterally movable plate elements which laterally adjoin the movable elements.

The movable elements can each be individual strip-type elements made of one material piece. However, they can also be composed of several partial pieces which are firmly or loosely connected to each other. In one embodiment, the movable elements have a straight edge at the side facing the respective assembly. As an alternative, this edge can also be already adapted to a typical topography of the assemblies.

Although the protection device 50 has been represented above such that the movable element moves in the vertical direction (i.e. withdraws), the movable element and the corresponding actuating devices 50B can be designed such that the movable element can be rotated about a horizontal axis, so that an axis of rotation is located at an end of the movable element opposite the assembly perpendicular to the direction of transport of the assembly. This is schematically shown at the outlet opening in FIG. 1. There, FIG. 1 shows an axis of rotation DA that is perpendicular to the image plane and to the direction of transport of the assembly. FIG. 1 also shows an arrow P1 indicating the sense of rotation of the movable element. At the inlet opening, an arrow P2 shows the alternative vertical direction of motion. Both movement mechanisms can be implemented individually or in combination in the process chamber.

In the arrangement represented in FIG. 1, at point in time t₁, no electronic assembly passes the opening at the exit of the process chamber 10. Correspondingly, the first and second movable elements 50A are positioned such that they nearly close the process chamber 10 or leave open an opening corresponding to a safety spacing between the first and second movable elements 50A with respect to each other or to adjacent structures.

At a later point in time t₂ (not shown), when a following component 30A is located at the place of the protection device 50, the controller 60 causes the actuating device 50B of the protection device 50 to adapt the position of the first and second movable elements 50A of the protection device 50 to the height of the following component 30A. Here, the first and second movable elements can be moved simultaneously and independently, so that the second movable element can follow the height profile at the bottom side of the assembly.

The height information of the components 30A can, for example, be determined with a measuring device 70 at a previous point in time to (not shown) before the electronic assembly 30 passes the opening 20. For example, via imaging methods, for example via a camera, a 3D model of the electronic assembly 30 can be established from which the height data of the components 30A can be read out. Alternatively, the position and height information can be obtained from component data resulting from the population of the printed circuit board with the components without requiring measurements. In the process, data files are generated which are transmitted to the controllers. Together with the position and speed data of the electronic assembly 30 relative to the process chamber 10, the controllers 60 can calculate at what time a certain component of a certain height passes the opening 20 at the location of the protection device 60. Correspondingly, the controller 60 can activate the actuating device 50B in order to position the movable element 50A corresponding to the height of the component 30A.

As an alternative or in combination, the height information of the components 30A can be detected with a mechanical sensor or/and interferometric sensors directly at the entry of the opening 20.

Preferably, the movable elements 50A (i.e. the first movable element and the optional second movable element) are made of stainless steel. Thereby, durable, dimensionally stable and conductive movable elements are obtained. Corrosion and wear are low, so that less maintenance is required. Furthermore, the conductivity takes care of a conductance of static electricity which arises, for example, during the transport on the electronic assembly. A better conductivity of static electricity can be achieved, for example, by soft conductive brushes at the end of the individually controllable movable elements which can dissipate frictional electricity. Since movable elements of stainless steel are dimensionally stable and can be manufactured very precisely, safety spacings to components or other parts of the process chamber can be minimized, so that the net opening through which protective gas can escape can be minimized. The net opening is understood as a net opening area through which protective gas can escape. The net opening area corresponds to the difference between the opening area reduced by the individually controllable movable elements and the assembly's cross-sectional area.

If lesser demands are put on precision and minimization of consumables and wear, a conductive, temperature-stable plastic can also be used as the material for the movable elements whereby the manufacturing costs for the process chamber can be reduced.

As an actuating device, preferably electric, electromechanical or pneumatic driving means are used. For example, a stepper motor with a defined step size, a pneumatic piston with position detection, an electric motor with position detection of the movable element etc. could be used.

The controller 60 can communicate with the measuring device 70 and the actuating device 50B wirelessly or in a wired manner.

CAD data or 2D/3D data of the assemblies can be entered, for example, wirelessly to the measurement device 70 or the controller 60.

1. Process chamber for carrying out thermal processes in the manufacture of an electronic assembly, comprising:
at least one opening for introducing and/or removing the electronic assembly;
a device for supplying a gas;
a controllable protection device which is arranged on the opening in order to reduce a leakage of gas from the process chamber, wherein the controllable protection device comprises a first element movable as an integral piece which covers a width between the total width of the opening and the width of the electronic assembly;
a device for detecting data relating to the dimensions of the electronic assembly; and
a controller which can control the protection device on the basis of the data relating to the dimensions of the electronic assembly such that, when the electronic assembly passes through the opening, a defined spacing is constantly maintained between the electronic assembly and the first movable element.

2. Process chamber according to claim 1, wherein the controllable protection device comprises a second movable element which covers a width between the total width of the opening and a width the electronic assembly, wherein the first movable element and the second movable element are each movable as integral pieces and are individually controllable and are arranged such that they are disposed above and below the electronic assembly when the electronic assembly pass through the opening.

3. Process chamber according to claim 2, wherein the controllable protection device can control the second movable element such that, when the electronic assembly passes through the opening, a defined spacing between components on the bottom side of the electronic assembly and the second movable element can be kept constant.

4. Process chamber according to claim 1, wherein the device for detecting data relating to dimensions of the electronic assembly comprises a measuring device which detects the topography or the three-dimensional structure of the electronic assembly, respectively.

5. Process chamber according to claim 4, wherein the measuring device uses imaging 2D and/or 3D measuring methods, and/or optical measuring methods, and/or mechanical measuring methods, and/or acoustic measuring methods for detecting the topography of the electronic assembly.

6. Process chamber according to claim 1, wherein the device for detecting data is designed to adopt provided 2D and/or 3D data of the electronic assembly.

7. Process chamber according to claim 1, further comprising an actuating device by which the first and/or the second movable element can be simultaneously and independently moved in a vertical direction.

8. Process chamber according to claim 1, further comprises an actuating device by which the first and/or the second movable element can be simultaneously and independently rotated about a horizontal axis, so that an axis of rotation is located at an end of the movable element opposite the electronic assembly perpendicular to a direction of transport of the electronic assembly.

9. Process chamber according to claim 7, wherein the actuating device comprises an electric or pneumatic driving means.

10. Process chamber according to claim 1, wherein the first and/or the second movable element is made of stainless steel.

11. Process chamber according to claim 1, wherein the first and/or the second movable element is made of a conductive plastic that is stable up to 280° C.

12. Process chamber according to claim 4, wherein the measuring device is selected from the group consisting of imaging 2D and/or 3D measuring devices, optical measuring devices, mechanical measuring devices, and acoustic measuring devices.

13. An electronic assembly process chamber comprising:
a process chamber;
an opening in said process chamber having a width dimension and a length dimension, the width dimension and the length dimension configured to allowing an electronic assembly having components to pass through said opening;
a movable element comprising an integral piece selectively positioned to cover said opening, the movable element having an edge capable of being positioned to a location within the width dimension of said opening and extend alone the length dimension of said opening;
an actuating device coupled to said movable element, said actuating device capable of moving the edge of said movable element to the location;
a topography measuring device, said topography measuring device capable of measuring a topography of the electronic assembly; and
a controller coupled to said actuating device, said controller receiving data from said topography measuring device of the topography of the electronic assembly and controlling positioning of the edge of said movable element to a selected location adjacent the electronic assembly based on the data of the topography of the electronic assembly,
whereby loss of a protective gas within said process chamber is reduced.

14. An electronic assembly process chamber according to claim 13 wherein:
the integral piece comprises one piece.

15. An electronic assembly process chamber according to claim 13 wherein:
wherein the integral piece comprises several parts connected to each other and attached to a common mount, wherein the several parts move together.

16. An electronic assembly process chamber according to claim 13 wherein:
wherein the edge is straight.

17. An electronic assembly process chamber according to claim 13 wherein:
wherein the edge is adapted to the topography of the electronic assembly.
